(19) United States
(12) Patent Application Publication
(10) Pub. No.: US 2026/0045217 A1
(43) Pub. Date: Feb. 12, 2026

(54) DISPLAY PANEL AND ELECTRONIC DEVICE INCLUDING THE SAME

(71) Applicant: SAMSUNG DISPLAY CO., LTD., YONGIN-SI (KR)

(72) Inventors: GUN HEE KIM, Yongin-si (KR); HYANG-A PARK, Yongin-si (KR); SEUNG-JUN LEE, Yongin-si (KR)

(21) Appl. No.: 19/206,154

(22) Filed: May 13, 2025

(30) Foreign Application Priority Data
Aug. 6, 2024 (KR) 10-2024-0104872

(51) Int. Cl. G09G 3/3233; G06F 3/0488; G09G 3/20; H10K 59/131

(52) U.S. Cl. CPC G09G 3/3233; G09G 3/2007; G06F 3/0488; G09G 2300/0426; G09G 2300/0819; G09G 2300/0842; G09G 2300/0861; G09G 2310/08; G09G 2320/0233; G09G 2320/041; G09G 2354/00; H10K 59/131

(57) ABSTRACT

A display panel includes a pixel including a pixel circuit and a light-emitting diode, a data line configured to provide a data signal to the pixel, a gate line configured to provide a gate signal to the pixel, and a power line configured to provide a power signal to the pixel. The pixel circuit includes a driving transistor, a switching transistor, a compensation transistor, and a sub-compensation transistor. The sub-compensation transistor is configured to transfer a compensation signal to a sub-control electrode of the driving transistor and is configured to be controlled by the same signal as the compensation transistor.

### CROSS-REFERENCE TO RELATED APPLICATIONS

This application claims priority under 35 U.S.C § 119 to Korean Patent Application No. 10-2024-0104872, filed on Aug. 6, 2024, the disclosure of which is incorporated by reference herein in its entirety.

### TECHNICAL FIELD

Embodiments of the present disclosure relate to a display panel, and more particularly, to a display panel designed to improve image quality at low grayscale levels by changing the threshold voltage of a driving transistor.

### DISCUSSION OF RELATED ART

A display device typically includes a display panel, a signal control circuit, a gate driving circuit, a data driving circuit, and a light-emission control circuit. The display panel typically includes a plurality of gate lines, a plurality of data lines, and a plurality of pixels connected to the plurality of gate lines and the plurality of data lines.

Each of the plurality of pixels may include a pixel circuit and a light-emitting diode. The pixel circuit may include a driving transistor, which controls the current flowing through the light-emitting diode. The luminance of light emitted from the light-emitting diode corresponds to the current flowing through the light-emitting diode.

The threshold voltage of the driving transistor can vary depending on the temperature. When the threshold voltage changes, the current flowing through the light-emitting diode and the luminance of the light emitted from the light-emitting diode can also change.

### SUMMARY

Embodiments of the present disclosure provide a display panel configured to improve image quality in low grayscale by changing the threshold voltage of the driving transistor.

A display panel according to an embodiment of the present disclosure may include pixels, data lines, gate lines, and power lines. Each pixel may include a pixel circuit and a light-emitting diode. The data lines may be configured to provide data signals to the pixels. The gate lines may be configured to provide gate signals to the pixels. The power lines may be configured to provide power signals to the pixels. The pixel circuit may include a driving transistor, a switching transistor, a compensation transistor, and a sub-compensation transistor. The driving transistor may be electrically connected to the light-emitting diode. The driving transistor may include an input electrode, an output electrode, a control electrode, and a sub-control electrode. The switching transistor may be configured to be controlled by a gate signal and may be disposed between the data line and the driving transistor. The compensation transistor may be disposed between the output electrode and the control electrode of the driving transistor. The sub-compensation transistor may be configured to transfer a compensation signal to the sub-control electrode of the driving transistor. The sub-compensation transistor may be configured to be controlled by the same signal as the compensation transistor.

In an embodiment of the present disclosure, a voltage value of the compensation signal may be greater than a voltage value of the power signal. In an embodiment of the present disclosure, when the ambient temperature decreases, a voltage value of the compensation signal may decrease.

The display panel according to an embodiment of the present disclosure may further include an emission control line, a first emission transistor, a second emission transistor, and an emission compensation transistor. The emission control line may be configured to provide an emission control signal to the pixels. The first emission transistor may be configured to be controlled by the emission control signal and may be disposed between the power line and the driving transistor. The second emission transistor may be configured to be controlled by the emission control signal and may be disposed between the driving transistor and the light-emitting diode. The emission compensation transistor may be configured to be controlled by the emission control signal and may be disposed between the power line and the sub-control electrode of the driving transistor.

The display panel according to an embodiment of the present disclosure may further include a capacitor. The capacitor may be disposed between the power line and the compensation transistor.

The display panel according to an embodiment of the present disclosure may further include a first initialization line and a first initialization transistor. The first initialization line may be configured to provide a first initialization signal to the pixels. The first initialization transistor may be disposed between the first initialization line and the control electrode of the driving transistor. The first initialization transistor may be configured to turn on simultaneously with the compensation transistor for a predetermined period of time.

The display panel according to an embodiment of the present disclosure may further include a second initialization line and a second initialization transistor. The second initialization line may be configured to provide a second initialization signal to the pixels. The second initialization transistor may be disposed between the second initialization line and the light-emitting diode. The second initialization transistor may be configured to transfer the second initialization signal to the light-emitting diode.

The display panel according to an embodiment of the present disclosure may further include a bias signal line and a bias transistor. The bias signal line may be configured to provide a bias signal to the pixels. The bias transistor may be disposed between the bias signal line and the driving transistor. The bias transistor may be configured to be controlled by the same signal as the second initialization transistor.

A display panel according to an embodiment of the present disclosure may include pixels, data lines, gate lines, power lines, and an emission control line. Each pixel may include a pixel circuit and a light-emitting diode. The data lines may be configured to provide data signals to the pixels. The gate lines may be configured to provide gate signals to the pixels. The power lines may be configured to provide power signals to the pixels. The emission control line may be configured to provide emission control signals to the pixels. The pixel circuit may include a driving transistor, a switching transistor, a first emission transistor, a second emission transistor, and an emission compensation transistor. The driving transistor may be electrically connected to the light-emitting diode. The driving transistor may include an input electrode, an output electrode, a control electrode, and a sub-control electrode. The switching transistor may be configured to be controlled by a gate signal and may be disposed between the data line and the driving transistor. The first emission transistor may be configured to be controlled by the emission control signal and may be disposed between the power line and the driving transistor. The second emission transistor may be configured to be controlled by the emission control signal and may be disposed between the driving transistor and the light-emitting diode. The emission compensation transistor may be configured to be controlled by the emission control signal and may be disposed between the power line and the sub-control electrode of the driving transistor.

The display panel according to an embodiment of the present disclosure may further include a compensation transistor and a sub-compensation transistor. The compensation transistor may be disposed between the output electrode and the control electrode of the driving transistor. The sub-compensation transistor may be configured to transfer a compensation signal to the sub-control electrode of the driving transistor. The sub-compensation transistor may be configured to be controlled by the same signal as the compensation transistor.

In an embodiment of the present disclosure, a voltage value of the compensation signal may be greater than a voltage value of the power signal. In an embodiment, when an ambient temperature decreases, the voltage value of the compensation signal may decrease. The display panel according to an embodiment of the present disclosure may further include a capacitor, which may be disposed between the power line and the compensation transistor.

The display panel according to an embodiment of the present disclosure may further include a first initialization line and a first initialization transistor. The first initialization line may be configured to provide a first initialization signal to the pixels. The first initialization transistor may be disposed between the first initialization line and the control electrode of the driving transistor. The first initialization transistor may be configured to be turned on simultaneously with the compensation transistor for a predetermined period of time.

The display panel according to an embodiment of the present disclosure may further include a second initialization line and a second initialization transistor. The second initialization line may be configured to provide a second initialization signal to the pixels. The second initialization transistor may be disposed between the second initialization line and the light-emitting diode. The second initialization transistor may be configured to transfer the second initialization signal to the light-emitting diode.

The display panel according to an embodiment of the present disclosure may further include a bias signal line and a bias transistor. The bias signal line may be configured to provide a bias signal to the pixels. The bias transistor may be disposed between the bias signal line and the driving transistor. The bias transistor may be configured to be controlled by the same signal as the second initialization transistor.

In an embodiment of the present disclosure, the voltage value of the data signal may range from about 0.5 V to about 6.8 V. The voltage value of the bias signal may range from about 5.0 V to about 6.0 V. The voltage value of the power signal may range from about 4.1 V to about 5.1 V. The voltage value of the first initialization signal may range from about −3.0 V to about −2.0 V. The voltage value of the second initialization signal may range from about −1.9 V to about −0.5 V.

A display panel according to an embodiment of the present disclosure may include a metal pattern, a first semiconductor pattern, a first conductive pattern, a second conductive pattern, a second semiconductor pattern, and a third conductive pattern. The metal pattern may include a first lower sub-electrode section. The first semiconductor pattern may be disposed on the metal pattern and may include a first lower-semiconductor portion, a second lower-semiconductor portion, a third lower-semiconductor portion, and a fourth lower-semiconductor portion. The first lower-semiconductor portion may overlap the first lower sub-electrode section. The second lower-semiconductor portion may extend from one end of the first lower-semiconductor portion, and the third lower-semiconductor portion may extend from the other end. The fourth lower-semiconductor portion may be spaced apart from the second lower-semiconductor portion. The first conductive pattern may be disposed on the first semiconductor pattern and may include a first lower-electrode portion, a second lower-electrode portion, a third lower-electrode portion, and a fourth lower-electrode portion. The first lower-electrode portion may overlap the first lower-semiconductor portion, and the second lower-electrode portion may be spaced apart from the first lower-electrode portion. The second lower-electrode portion may overlap the second lower-semiconductor portion. The third lower-electrode portion may extend from one end of the second lower-electrode portion and overlap the third lower-semiconductor portion. The fourth lower-electrode portion may extend from the other end of the second lower-electrode portion and overlap the fourth lower-semiconductor portion.

The second conductive pattern may be disposed on the first conductive pattern and may include a first upper sub-electrode section. The first upper sub-electrode section may overlap the first lower-electrode portion. The second semiconductor pattern may be disposed on the second conductive pattern and may include a first upper-semiconductor portion and a second upper-semiconductor portion. The second upper-semiconductor portion may be spaced apart from the first upper-semiconductor portion. The third conductive pattern may be disposed on the second semiconductor pattern and may include a first upper-electrode portion and a second upper-electrode portion. The first upper-electrode portion may overlap the first upper-semiconductor portion, and the second upper-electrode portion may overlap the second upper-semiconductor portion. The second upper-electrode portion may extend from one end of the first upper-electrode portion.

The display panel according to an embodiment of the present disclosure may further include a connection electrode pattern. The connection electrode pattern may be disposed on the third conductive pattern. The connection electrode pattern may include a first connection electrode, a second connection electrode, and a third connection electrode. The first connection electrode may contact the first lower-electrode portion through a first contact hole and the second upper-semiconductor portion through a second contact hole. The second connection electrode may contact the fourth lower-semiconductor portion through a third contact hole and the first lower sub-electrode section through a fourth contact hole. The third connection electrode may contact the first upper-semiconductor portion through a fifth contact hole and the sub-electrode section through a sixth contact hole.

In an embodiment of the present disclosure, the metal pattern may further include a second lower sub-electrode section and a third lower sub-electrode section. The connection electrode pattern may further include a fourth connection electrode and a fifth connection electrode. The fourth connection electrode may contact the first upper-semiconductor portion through a seventh contact hole and the third lower sub-electrode section through an eighth contact hole. The fifth connection electrode may contact the second lower sub-electrode section through a ninth contact hole and the fourth lower-semiconductor portion through a tenth contact hole.

According to an embodiment of the present disclosure, an electronic device includes a processor, a memory having stored application programs for execution by the processor, a display device, and a user interface. The display device includes a display panel. The display panel includes a pixel including a pixel circuit and a light-emitting diode, a data line configured to provide a data signal to the pixel, a gate line configured to provide a gate signal to the pixel, and a power line configured to provide a power signal to the pixel. The pixel circuit includes a driving transistor electrically connected to the light-emitting diode and including an input electrode, an output electrode, a control electrode, and a sub-control electrode, a switching transistor configured to be controlled by the gate signal and disposed between the data line and the driving transistor, a compensation transistor disposed between the output electrode and the control electrode of the driving transistor, and a sub-compensation transistor configured to transfer a compensation signal to the sub-control electrode of the driving transistor and configured to be controlled by a same signal as the compensation transistor. The user interface is configured to sense user input via touch or cursor select of an icon presented on the display panel. The processor is caused to execute one or more of the stored application programs upon receipt of the user input.

In an embodiment of the present disclosure, the stored application programs include one or more of a camera application, an audiovisual streaming application, or a telephone application.

In an embodiment of the present disclosure, the user interface is a touch screen embedded in the display panel, wherein the touch screen includes touch sensors for sensing a touch or a tap by a user.

According to an embodiment of the present disclosure, by changing the threshold voltage of the driving transistor, it becomes possible to provide a display panel that is capable of improving image quality in low grayscale environments.

### BRIEF DESCRIPTION OF THE DRAWINGS

The above and other features of the present disclosure will become more apparent by describing in detail embodiments thereof with reference to the accompanying drawings, in which:

FIG. 1 is a block diagram illustrating a display device according to an embodiment of the present disclosure;

FIG. 2A is an exemplary equivalent circuit diagram illustrating a pixel according to an embodiment of the present disclosure;

FIG. 2B is an exemplary equivalent circuit diagram illustrating a pixel in which an emission compensation transistor is omitted from the pixel shown in FIG. 2A;

FIG. 2C is an exemplary equivalent circuit diagram illustrating a pixel in which a sub-compensation transistor is omitted from the pixel shown in FIG. 2A;

FIG. 2D is a waveform diagram illustrating signals provided to the pixels of a display device according to an embodiment of the present disclosure;

FIG. 3 is a plan view illustrating the layout of a pixel circuit according to an embodiment of the present disclosure

FIGS. 4A to 4G are plan views of any one of a plurality of patterns.

FIGS. 5A to 5F are exemplary diagrams illustrating sequentially stacked shapes of at least some of FIGS. 4A to 4G, as an example, in accordance with a manufacturing process.

FIG. 6A is an exemplary equivalent circuit diagram illustrating a pixel according to an embodiment of the present disclosure; and

FIG. 6B is a waveform diagram illustrating signals provided to the pixels of a display device according to an embodiment of the present disclosure.

FIG. 7 is a diagram illustrating an electronic device according to an embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

When something is described to be “output” to an element, it shall be construed as being output to the element directly but also as possibly being output via another element. On the other hand, if something is described to be “directly output” to an element, it shall be construed that output is made via no other element. Moreover, when a component is described to be “on” an element, it shall be appreciated that said component is above or below said element, and not necessarily above said element in a gravitational direction.

Embodiments of the present disclosure relate to a display device capable of improving image quality at low grayscale levels by compensating for threshold voltage variations in a driving transistor. These variations, which may occur due to ambient temperature fluctuations, can lead to unintended changes in current flow through a light-emitting diode, resulting in inconsistent luminance and degraded display performance. To address this issue, the display device according to embodiments may utilize a compensation mechanism that dynamically adjusts the voltage at a sub-control electrode of the driving transistor, which may stabilize its operating characteristics and prevent or reduce unwanted brightness fluctuations.

Embodiments of the present application may utilize compensation transistors, including a sub-compensation transistor and an emission compensation transistor, which may work in conjunction to regulate the driving transistor's threshold voltage. A compensation signal may be modulated based on temperature changes, counteracting shifts in the driving transistor's electrical properties and providing consistent drive current to the light-emitting diode. Additionally, a temperature sensor may detect ambient temperature variations in real-time, enabling precise compensation adjustments. This approach may effectively mitigate the effects of leakage current and improve the black level expression capability of the display device, reducing unintended emission in dark image regions.

By implementing the above compensation techniques, embodiments of the present disclosure may provide stable image quality under varying environmental conditions, for example, in low grayscale levels where luminance inconsistencies are most noticeable.

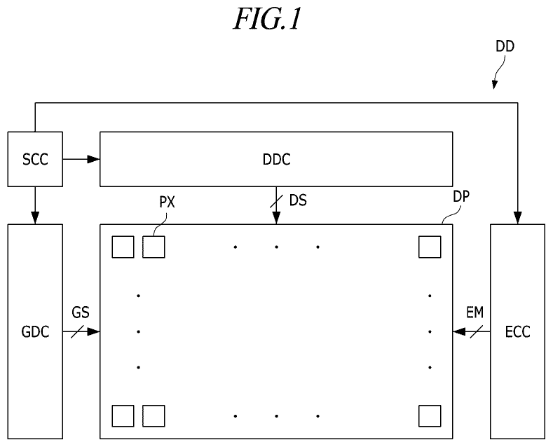

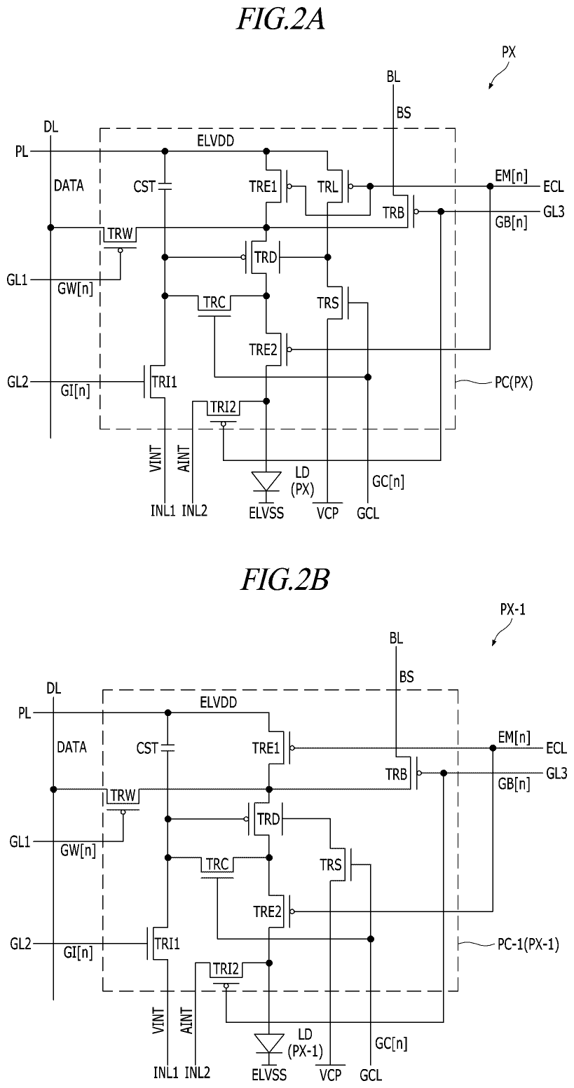

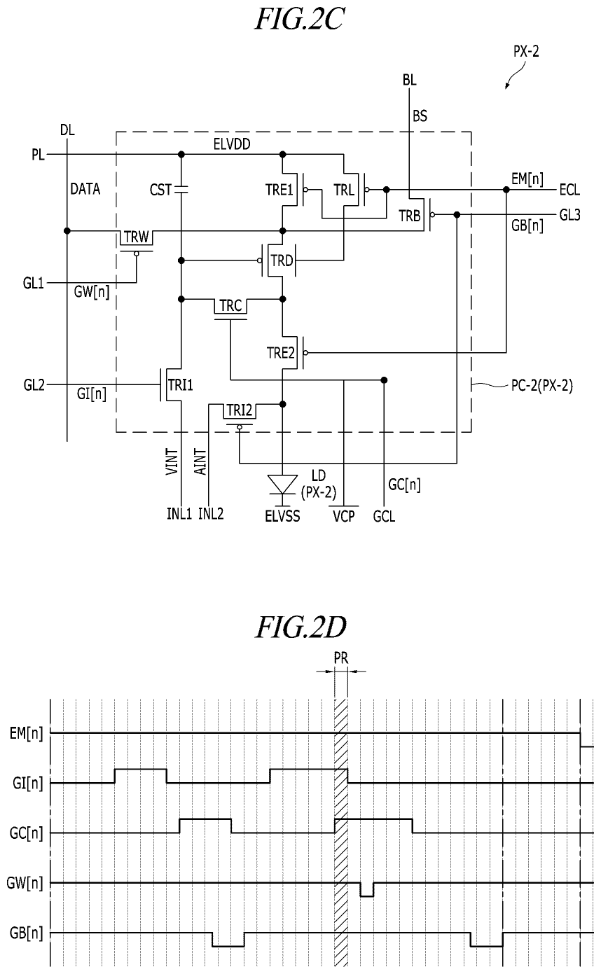

FIG. 1 is a block diagram of a display device DD according to an embodiment of the present disclosure. FIG. 2A is an exemplary equivalent circuit diagram illustrating a pixel PX according to an embodiment of the present disclosure. FIG. 2B is an exemplary equivalent circuit diagram illustrating a pixel PX-1 in which an emission compensation transistor TRL is omitted from the pixel PX shown in FIG. 2A. FIG. 2C is an exemplary equivalent circuit diagram illustrating a pixel PX-2 in which a sub-compensation transistor TRS is omitted from the pixel PX shown in FIG. 2A.

Referring to FIG. 1, the display device DD according to an embodiment of the present disclosure may include a display panel DP, a signal control circuit SCC, a gate driving circuit GDC, a data driving circuit DDC, and an emission control circuit ECC.

Referring to FIGS. 2A, 2B, and 2C, the display panel DP may include a data line DL, a power line PL, a first gate line GL1, a second gate line GL2, a third gate line GL3, a first initialization line INL1, a second initialization line INL2, a compensation signal line GCL, an emission control line ECL, a bias signal line BL, and a pixel PX. The pixel PX and lines illustrated in FIGS. 2A, 2B, and 2C may be provided in a plurality.

The data line DL may be configured to provide a data signal DS to the pixel PX. The power line PL may be configured to provide a first power signal ELVDD to the pixel PX. The first gate line GL1 may be configured to provide a first gate signal GW to the pixel PX. The second gate line GL2 may be configured to provide a second gate signal GI to the pixel PX. The third gate line GL3 may be configured to provide a third gate signal GB to the pixel PX.

The first initialization line INL1 may be configured to provide a first initialization signal VINT to the pixel PX. The second initialization line INL2 may be configured to provide a second initialization signal AINT to the pixel PX. The compensation signal line GCL may be configured to provide a compensation signal VCP to the pixel PX. The emission control line ECL may be configured to provide an emission control signal EM to the pixel PX. The bias signal line BL may be configured to provide a bias signal BS to the pixel PX.

The display panel DP according to an embodiment of the present disclosure may be a light-emitting display panel. For example, the display panel DP may be any one of an organic light-emitting display panel, a quantum dot light-emitting display panel, a micro-LED display panel, a liquid crystal display panel, an electrophoretic display panel, and an electrowetting display panel. The emission layer of an organic light-emitting display panel may include organic light-emitting materials. An inorganic light-emitting display panel may include a quantum dot light-emitting display panel and a micro-LED display panel based on inorganic materials. Hereinafter, the display panel DP will be described based on an organic light-emitting display panel. However, embodiments of the present disclosure are not limited thereto.

The signal control circuit SCC, e.g., a timing controller, may be configured to control the gate driving circuit GDC, the data driving circuit DDC, and the emission control circuit ECC. The signal control circuit SCC may be configured to receive image data and control signals from an external graphic control unit. The control signals may include, for example, a vertical synchronization signal, which distinguishes frame intervals, a horizontal synchronization signal, which distinguishes row intervals (e.g., a row identification signal), a data enable signal, which may be a high-level only during the section where data is output to indicate a section in which data is received, and clock signals. The gate driving circuit GDC may be configured to receive control signals from the signal control circuit SCC and provide gate control signals GS to the pixels PX through the plurality of gate lines.

In an embodiment of the present disclosure, the gate driving circuit GDC may be formed simultaneously with the pixels PX through a thin-film process. For example, the gate driving circuit GDC may be installed in the form of an oxide semiconductor TFT gate driver circuit (OSG) or an amorphous silicon TFT gate driver circuit (ASG).

The data driving circuit DDC may be configured to receive control signals from the signal control circuit SCC and provide data signals DS to the pixels PX through the data line DL. The emission control circuit ECC may be configured to receive control signals from the signal control circuit SCC and provide emission control signals EM to the pixels PX through the emission control line ECL. In an embodiment of the present disclosure, the gate driving circuit GDC and the emission control circuit ECC may be integrated into a single circuit without being separated.

FIG. 2A is an equivalent circuit diagram of a pixel PX according to an embodiment of the present disclosure.

Referring to FIG. 2A, in an embodiment of the present disclosure, at least one of the second gate line GL2, the first initialization line INL1, the second initialization line INL2, the compensation signal line GCL, the third gate line GL3, and the bias signal line BL may be omitted.

In an embodiment of the present disclosure, the voltage value of the data signal DS may be between about 0.5 V and about 6.8 V.

The voltage value of the first power signal ELVDD may be between about 4.1 V and about 5.1 V. For example, the voltage value of the first power signal ELVDD may be about 4.6 V. However, the voltage value of the first power signal ELVDD is not limited to what is described herein and may be adjusted according to embodiments of the present disclosure.

The voltage value of the first initialization signal VINT may be between about −3.0 V and about −2.0 V. For example, the voltage value of the first initialization signal VINT may be about −2.5 V. However, the voltage value of the first initialization signal VINT is not limited thereto, and may be adjusted according to embodiments of the present disclosure.

In an embodiment of the present disclosure, the voltage value of the second initialization signal AINT may be between about −1.9 V and about −0.5 V. For example, the voltage value of the second initialization signal AINT may be about −1.4 V. However, the voltage value of the second initialization signal AINT is not limited thereto, and may be adjusted according to embodiments of the present disclosure.

The voltage value of the third gate signal GB may be between about −8.0 V and about 6.5 V. The voltage value of the bias signal BS may be between about 5.0 V and about 6.0 V. For example, the voltage value of the bias signal BS may be about 5.5 V. However, the voltage value of the bias signal BS is not limited thereto, and may be adjusted according to embodiments of the present disclosure.

The pixel PX may include a pixel circuit PC and a light-emitting diode LD. The structure of the pixel PX according to embodiments of the present disclosure is not limited to the structure shown in FIG. 2A. For example, in an embodiment of the present disclosure, the pixel PX may be implemented in various forms to emit light from the light-emitting diode LD.

The pixel circuit PC may be configured to control the current flowing through the light-emitting diode LD in response to the data signal DS. The pixel circuit PC may include a driving transistor TRD, a switching transistor TRW, a compensation transistor TRC, a sub-compensation transistor TRS, a first emission transistor TRE1, a second emission transistor TRE2, an emission compensation transistor TRL, a capacitor CST, a first initialization transistor TRI1, a second initialization transistor TRI2, and a bias transistor TRB.

In the pixel circuit PC according to an embodiment of the present disclosure, at least one of the sub-compensation transistor TRS, the first emission transistor TRE1, the second emission transistor TRE2, the emission compensation transistor TRL, the capacitor CST, the first initialization transistor TRI1, the second initialization transistor TRI2, and the bias transistor TRB may be omitted.

In an embodiment of the present disclosure, the pixel PX may be a hybrid oxide polysilicon (HOP) pixel suitable for low-frequency driving. That is, the compensation transistor TRC, the sub-compensation transistor TRS, and the first initialization transistor TRI1 may each be an oxide thin-film transistor. In addition, the driving transistor TRD, the switching transistor TRW, the first emission transistor TRE1, the second emission transistor TRE2, the emission compensation transistor TRL, the second initialization transistor TRI2, and the bias transistor TRB may each be a low-temperature polycrystalline silicon (LTPS) thin-film transistor.

In an embodiment of the present disclosure, the driving transistor TRD, the switching transistor TRW, the first emission transistor TRE1, the second emission transistor TRE2, the emission compensation transistor TRL, the second initialization transistor TRI2, and the bias transistor TRB may each be either an NMOS transistor or a PMOS transistor. The compensation transistor TRC, the sub-compensation transistor TRS, and the first initialization transistor TRI1 may each be the other type of transistor (e.g., if the first set of transistors is NMOS, the second set is PMOS, and vice versa). However, the present disclosure is not limited thereto. For example, according to embodiments of the present disclosure, the pixel PX may be configured with various combinations of NMOS and PMOS transistors.

The driving transistor TRD may be configured to control the current flowing through the light-emitting diode LD in response to the voltage applied to the control electrode. The driving transistor TRD may be electrically connected to the light-emitting diode LD. The driving transistor TRD may include an input electrode, an output electrode, a control electrode, and a sub-control electrode. The input electrode may be one of the source electrode and the drain electrode, and the output electrode may be the other one of the source and drain electrodes. The control electrode may be a gate electrode. The sub-control electrode may be a back-gate electrode. When a predetermined signal is applied to the sub-control electrode, the threshold voltage of the driving transistor TRD may change.

The switching transistor TRW may be configured to be controlled by the first gate signal GW. The switching transistor TRW may be disposed between the data line DL and the driving transistor TRD. The switching transistor TRW may be configured to be turned on by the first gate signal GW to transfer at least a portion of the data signal DS to the input electrode of the driving transistor TRD.

The compensation transistor TRC may be disposed between the output electrode and the control electrode of the driving transistor TRD. The compensation transistor TRC may be configured to be controlled by the compensation control signal GC. When the compensation transistor TRC is turned on by the compensation control signal GC, the driving transistor TRD may become diode-connected, allowing its threshold voltage to be compensated.

The sub-compensation transistor TRS may be configured to transfer the compensation signal VCP to the sub-control electrode of the driving transistor TRD. The sub-compensation transistor TRS may be configured to be controlled by the same signal as the compensation transistor TRC. That is, the sub-compensation transistor TRS and the compensation transistor TRC are controlled by the same signal. The sub-compensation transistor TRS may be configured to be turned on by the compensation control signal GC to transfer the compensation signal VCP to the sub-control electrode of the driving transistor TRD. When the compensation signal VCP is applied to the sub-control electrode of the driving transistor TRD, the threshold voltage of the driving transistor TRD may change.

The threshold voltage of the driving transistor TRD may vary depending on the ambient temperature. That is, more or less current than intended may flow through the light-emitting diode LD depending on the ambient temperature, affecting brightness. For example, in case in which the driving transistor TRD is a PMOS transistor, an increase in ambient temperature generally decreases the absolute value of its threshold voltage, resulting in an increase in the current flowing through the light-emitting diode LD. As a result, the image quality of the display panel may deteriorate at low grayscale levels due to unintended luminance changes.

In an embodiment of the present disclosure, when the ambient temperature decreases, the voltage value of the compensation signal VCP may decrease. In an embodiment of the present disclosure, when the ambient temperature increases, the voltage value of the compensation signal VCP may increase. By varying the voltage value of the compensation signal VCP according to the ambient temperature, the change in the threshold voltage of the driving transistor TRD based on the ambient temperature may be offset or reduced. Accordingly, it is possible to prevent the image quality of the display panel from degrading at low grayscale levels. In an embodiment of the present disclosure, the ambient temperature may be detected by a temperature sensor installed in the display device DD. The temperature sensor may be disposed adjacent to the display panel DP to precisely detect a temperature change in the display panel DP.

For example, in an embodiment of the present disclosure, the compensation signal VCP is dynamically adjusted in response to changes in ambient temperature, which may mitigate the impact of threshold voltage variations in the driving transistor TRD. For example, when the ambient temperature decreases, the voltage value of the compensation signal VCP may also decrease, thereby counteracting an increase in the threshold voltage of TRD. Conversely, when the ambient temperature increases, the voltage value of the compensation signal VCP may increase, compensating for a reduction in the absolute value of the threshold voltage. By continuously modulating the compensation signal VCP in accordance with temperature fluctuations, the system may stabilize the operating characteristics of the driving transistor TRD, which may prevent or reduce unintended variations in the current supplied to the light-emitting diode LD. As a result, brightness inconsistencies—for example, those that may disrupt image quality in low grayscale levels—can be effectively minimize or reduced. In an embodiment, the ambient temperature may be detected in real time by a temperature sensor disposed adjacent to the display panel DP. This sensor may enable precise detection of temperature variations within the display environment, allowing the compensation mechanism to respond proactively and accurately maintain display performance.

In an embodiment of the present disclosure, the voltage value of the compensation signal VCP may be higher than the voltage value of the first power signal ELVDD. In a case in which the driving transistor TRD is a PMOS transistor, the threshold voltage of the driving transistor TRD may undergo a negative shift if the voltage value of the compensation signal VCP is higher than the voltage value of the first power signal ELVDD. That is, the compensation signal VCP may contribute to offsetting or reducing the change in the threshold voltage of the driving transistor TRD based on the ambient temperature. For example, when the voltage value of the first power signal ELVDD is about 4.6 V, the voltage value of the compensation signal VCP may be greater than about 4.6 V. However, the voltage value of the compensation signal VCP is not limited thereto.

The first emission transistor TRE1 may be configured to be controlled by the emission control signal EM. The first emission transistor TRE1 may be disposed between the power line PL and the driving transistor TRD. The first emission transistor TRE1 may be configured to be turned on by the emission control signal EM to transfer the first power signal ELVDD to the input electrode of the driving transistor TRD.

The second emission transistor TRE2 may be configured to be controlled by the emission control signal EM. The second emission transistor TRE2 may be disposed between the driving transistor TRD and the light-emitting diode LD. The second emission transistor TRE2 may be configured to be turned on by the emission control signal EM to electrically connect the output electrode of the driving transistor TRD with the light-emitting diode LD.

The emission compensation transistor TRL may be configured to be controlled by the emission control signal EM. The emission compensation transistor TRL may be disposed between the power line PL and the sub-control electrode of the driving transistor TRD. The emission compensation transistor TRL may be configured to be turned on in response to the emission control signal EM and deliver the first power signal ELVDD to the sub-control electrode of the driving transistor TRD. The threshold voltage of the driving transistor TRD may be changed when the first power signal ELVDD is provided to the sub-control electrode of the driving transistor TRD. That is, the first power signal ELVDD may contribute to offsetting or reducing the change in the threshold voltage of the driving transistor TRD based on the ambient temperature.

For example, in an embodiment of the present disclosure, the emission compensation transistor TRL may be configured to regulate the threshold voltage of the driving transistor TRD by selectively supplying a stabilized voltage signal to its sub-control electrode. For example, the emission compensation transistor TRL may be controlled by the emission control signal EM and be positioned between the power line PL and the sub-control electrode of the driving transistor TRD. When the emission compensation transistor TRL is turned on by the emission control signal EM, the emission compensation transistor TRL may deliver the first power signal ELVDD to the sub-control electrode, thereby influencing the operating characteristics of the driving transistor TRD. By applying the first power signal ELVDD to this electrode, the threshold voltage of the driving transistor TRD may be adjusted dynamically, compensating for fluctuations that would otherwise occur due to ambient temperature variations. As a result, this mechanism may contribute to stabilizing current flow through the driving transistor TRD, which may prevent unintended changes in brightness, for example, in low grayscale image regions. This compensation technique may allow for the image quality to remain consistent, even as the display device operates under varying temperature conditions.

The capacitor CST may be disposed between the power line PL and the compensation transistor TRC. The capacitor CST may be configured to store a charge corresponding to the data signal DS. Based on the amount of charge stored in the capacitor CST, the current flowing through the driving transistor TRD when the first emission transistor TRE1 and the second emission transistor TRE2 are turned on may be determined.

The first initialization transistor TRI1 may be disposed between the first initialization line INL1 and the control electrode of the driving transistor TRD. The first initialization transistor TRI1 may be configured to be controlled by the second gate signal GI. The first initialization transistor TRI1 may be configured to be turned on in response to the second gate signal GI and transfer at least a portion of the first initialization signal VINT to the control electrode of the driving transistor TRD.

The second initialization transistor TRI2 may be disposed between the second initialization line INL2 and the light-emitting diode LD. The second initialization transistor TRI2 may be configured to be controlled by the third gate signal GB. The second initialization transistor TRI2 may be configured to deliver the second initialization signal AINT to the light-emitting diode LD. That is, the second initialization transistor TRI2 may be configured to be turned on in response to the third gate signal GB and transfer at least a portion of the second initialization signal AINT to the light-emitting diode LD.

The second initialization transistor TRI2 may be utilized to improve the black level expression capability of the pixel PX. When the second initialization transistor TRI2 is turned on, the parasitic capacitance of the light-emitting diode LD may discharge, reducing the leakage current generated by the driving transistor TRD. As a result, when implementing black luminance, the emission of the light-emitting diode LD due to leakage current may be prevented or reduced, thereby improving the black level expression capability.

The bias transistor TRB may be disposed between the bias signal line BL and the driving transistor TRD. The bias transistor TRB may be configured to be controlled by the same signal GB as the second initialization transistor TRI2. That is, the bias transistor TRB may be configured to be turned on in response to the third gate signal GB and deliver the bias signal BS to the input electrode of the driving transistor TRD. The bias signal BS may contribute to keeping the driving transistor TRD turned on for a predetermined period of time.

The light-emitting diode LD may be configured to emit light at a predetermined luminance in response to the current provided by the pixel circuit PC. To achieve this, the voltage value of the first power signal ELVDD may be set higher than the voltage value of the second power signal ELVSS. One end of the light-emitting diode LD may be electrically connected to the second emission transistor TRE2, and the second power signal ELVSS may be applied to the other end of the light-emitting diode LD. In an embodiment of the present disclosure, the voltage value of the second power signal ELVSS may range from about −0.9 V to about −1.9 V. For example, the voltage value of the second power signal ELVSS may be about −1.4 V. However, the voltage value of the second power signal ELVSS is not limited thereto. For example, according to embodiments of the present disclosure, the light-emitting diode LD may be, but is not limited to, an organic light-emitting diode (OLED).

FIG. 2B is an exemplary equivalent circuit diagram of a pixel PX-1 in which the emission compensation transistor TRL is omitted from the pixel PX shown in FIG. 2A.

Referring to FIG. 2B, in an embodiment of the present disclosure, at least one of the second gate line GL2, the first initialization line INL1, the second initialization line INL2, the compensation signal line GCL, the third gate line GL3, the emission control line ECL, and the bias signal line BL may be omitted.

The pixel PX-1 may include a pixel circuit PC-1 and a light-emitting diode LD. The pixel circuit PC-1 may include a driving transistor TRD, a switching transistor TRW, a compensation transistor TRC, a sub-compensation transistor TRS, a first emission transistor TRE1, a second emission transistor TRE2, a capacitor CST, a first initialization transistor TRI1, a second initialization transistor TRI2, and a bias transistor TRB.

In the pixel circuit PC-1 according to an embodiment of the present disclosure, at least one of the first emission transistor TRE1, the second emission transistor TRE2, the capacitor CST, the first initialization transistor TRI1, the second initialization transistor TRI2, and the bias transistor TRB may be omitted. For convenience of explanation, a further description of components and technical aspects previously described with reference to FIGS. 1 and FIG. 2A is omitted.

FIG. 2C is an exemplary equivalent circuit diagram of a pixel PX-2 in which the sub-compensation transistor TRS is omitted from the pixel PX shown in FIG. 2A.

Referring to FIG. 2C, in an embodiment of the present disclosure, at least one of the second gate line GL2, the first initialization line INL1, the second initialization line INL2, the compensation signal line GCL, the third gate line GL3, and the bias signal line BL may be omitted.

The pixel PX-2 may include a pixel circuit PC-2 and a light-emitting diode LD. The pixel circuit PC-2 may include a driving transistor TRD, a switching transistor TRW, a compensation transistor TRC, a first emission transistor TRE1, a second emission transistor TRE2, an emission compensation transistor TRL, a capacitor CST, a first initialization transistor TRI1, a second initialization transistor TRI2, and a bias transistor TRB.

In the pixel circuit PC-2 according to an embodiment of the present disclosure, at least one of the compensation transistor TRC, the capacitor CST, the first initialization transistor TRI1, the second initialization transistor TRI2, and the bias transistor TRB may be omitted. For convenience of explanation, a further description of components and technical aspects previously described with reference to FIGS. 1 and FIG. 2A is omitted.

FIG. 2D is a waveform diagram illustrating signals provided to the pixels PX, PX-1, PX-2 according to an embodiment of the present disclosure.

Referring to FIG. 2D, the first initialization transistor TRI1 of the pixels PX, PX-1, PX-2 according to an embodiment of the present disclosure may be configured to be turned on simultaneously with the compensation transistor TRC for a predetermined period PR.

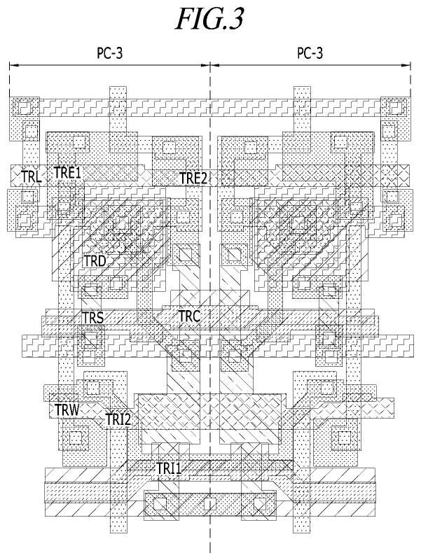

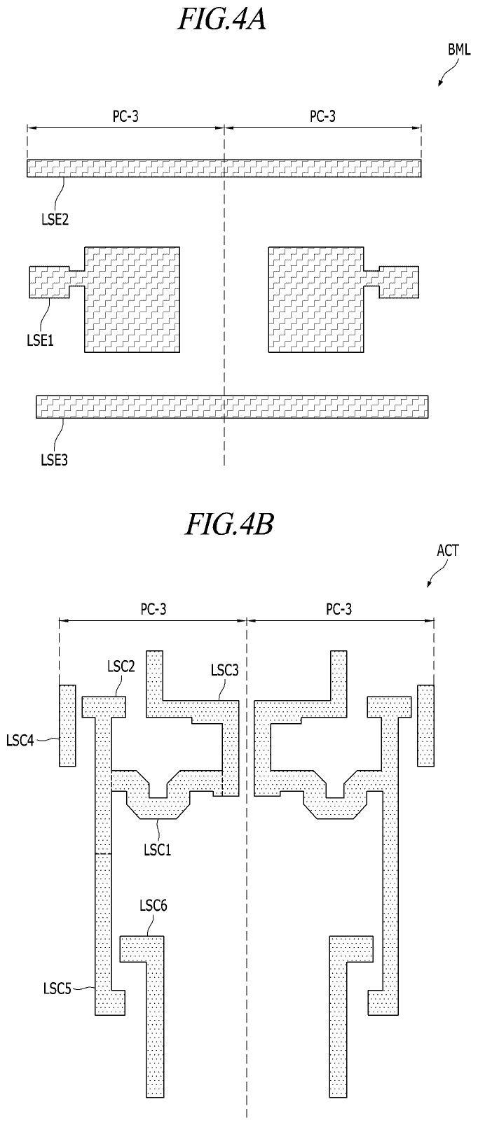

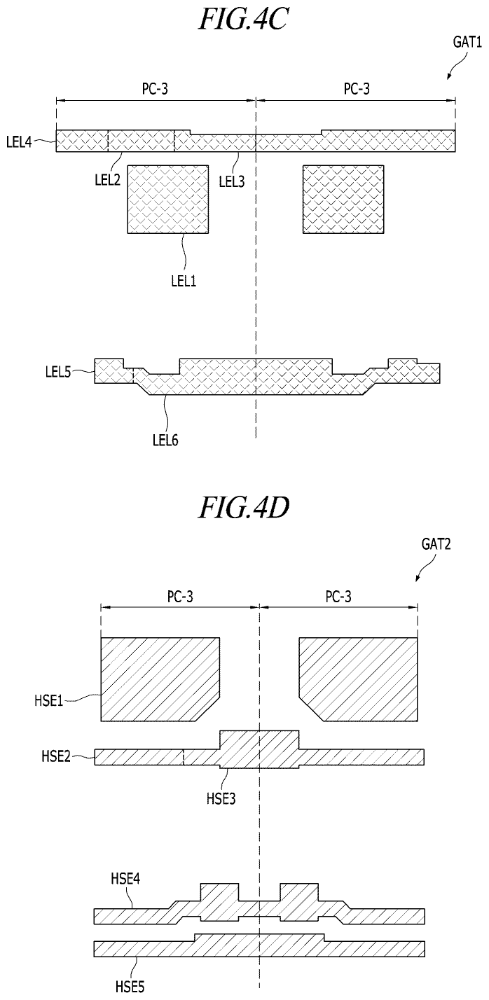

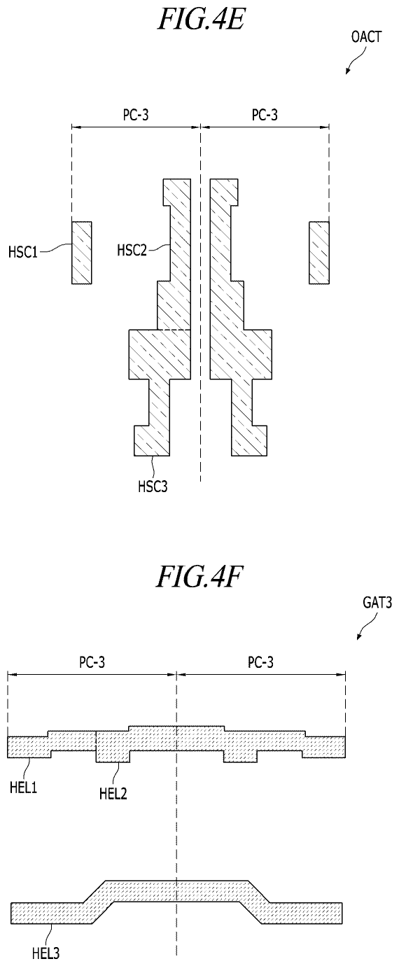

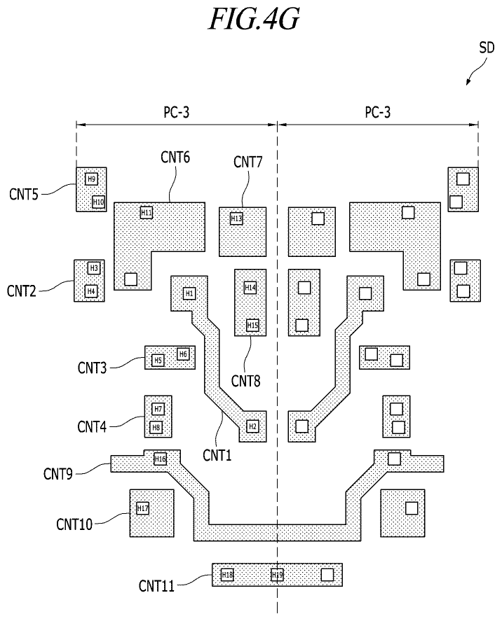

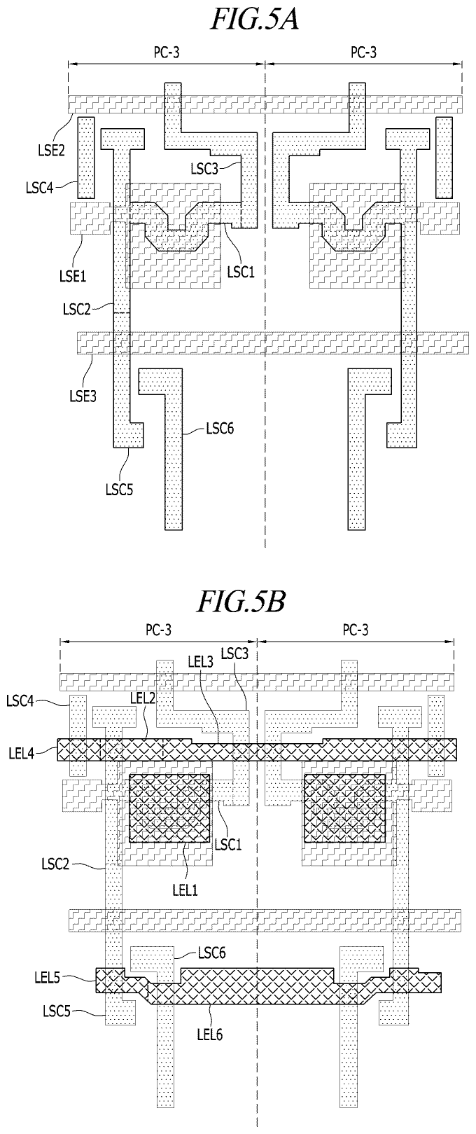

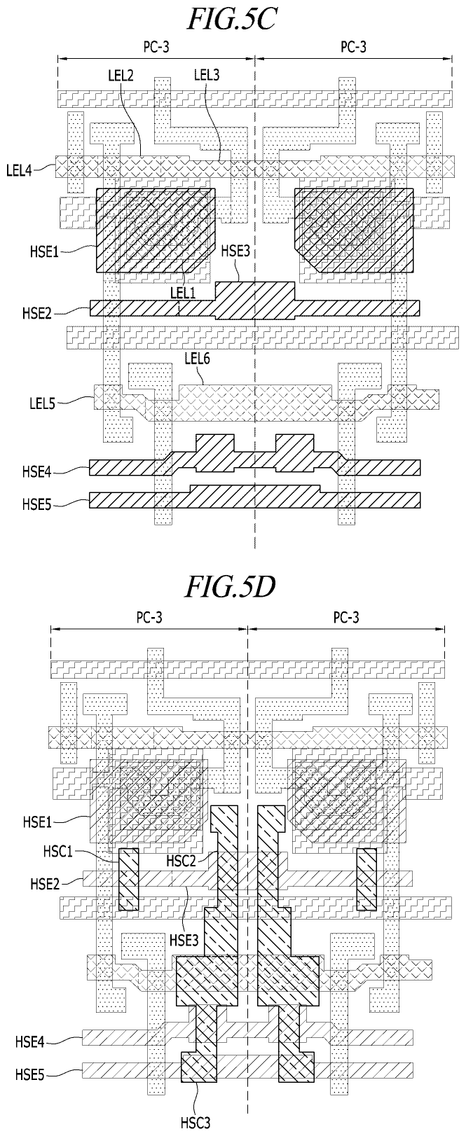

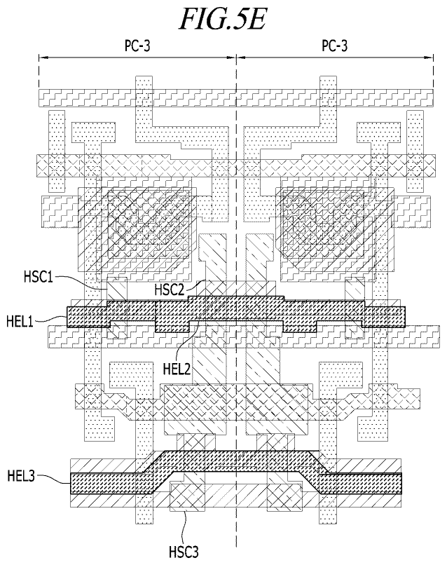

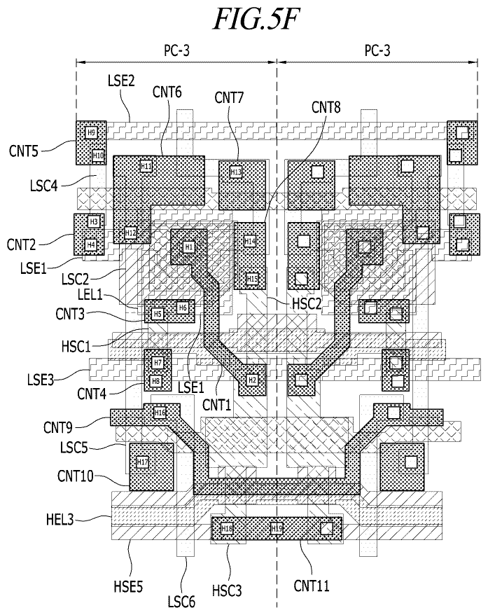

FIG. 3 is a plan view illustrating the layout of a pixel circuit PC-3 according to an embodiment of the present disclosure. The layout of the pixel circuit PC-3 may have a plurality patterns superimposed. FIGS. 4A to 4G are plan views, each illustrating one of the plurality of patterns. FIGS. 5A to 5F are exemplary diagrams illustrating shapes in which at least some of the patterns from FIGS. 4A to 4G are sequentially superimposed according to a manufacturing process.

Referring to FIGS. 3 through 4G, the pixel circuit PC-3 of the display panel DP according to an embodiment of the present disclosure may include a metal pattern BML, a first semiconductor pattern ACT, a first conductive pattern GAT1, a second conductive pattern GAT2, a second semiconductor pattern OACT, a third conductive pattern GAT3, and a connection electrode pattern SD.

FIG. 4A is a plan view of the metal pattern BML. Referring to FIG. 4A, the metal pattern BML may include a first lower-sub-electrode portion LSE1, a second lower-sub-electrode portion LSE2, and a third lower-sub-electrode portion LSE3. In an embodiment of the present disclosure, at least one of the second lower-sub-electrode portion LSE2 and the third lower-sub-electrode portion LSE3 may be omitted.

The second lower-sub-electrode portion LSE2 may be electrically connected to the power line PL. The third lower-sub-electrode portion LSE3 may be electrically connected to the compensation signal line GCL. The second lower-sub-electrode portion LSE2 may be configured to provide the first power signal ELVDD. The third lower-sub-electrode portion LSE3 may be configured to provide the compensation signal VCP. In an embodiment of the present disclosure, the power line PL and the compensation signal line GCL may each be electrically connected to any one of the first conductive pattern GAT1, the second conductive pattern GAT2, and the third conductive pattern GAT3.

FIG. 4B is a plan view of the first semiconductor pattern ACT. Referring to FIGS. 3 and 4B, the first semiconductor pattern ACT may include a first lower-semiconductor portion LSC1, a second lower-semiconductor portion LSC2, a third lower-semiconductor portion LSC3, a fourth lower-semiconductor portion LSC4, a fifth lower-semiconductor portion LSC5, and a sixth lower-semiconductor portion LSC6.

The first lower-semiconductor portion LSC1, the second lower-semiconductor portion LSC2, the third lower-semiconductor portion LSC3, and the fourth lower-semiconductor portion LSC4 may be elements constituting the driving transistor TRD, the first emission transistor TRE1, the second emission transistor TRE2, and the emission compensation transistor TRL, respectively. The second lower-semiconductor portion LSC2 may extend from one end of the first lower-semiconductor portion LSC1. The third lower-semiconductor portion LSC3 may extend from the other end of the first lower-semiconductor portion LSC1. The fourth lower-semiconductor portion LSC4 may be spaced apart from the second lower-semiconductor portion LSC2. The fifth lower-semiconductor portion LSC5 may extend from the second lower-semiconductor portion LSC2. The sixth lower-semiconductor portion LSC6 may be spaced apart from the fifth lower-semiconductor portion LSC5.

In an embodiment of the present disclosure, each of the first lower-semiconductor portion LSC1 to the sixth lower-semiconductor portion LSC6 may include a silicon semiconductor. The silicon semiconductor may include at least one of amorphous silicon and polycrystalline silicon. For example, each of the first lower-semiconductor portion LSC1 to the sixth lower-semiconductor portion LSC6 may include low-temperature polycrystalline silicon (LTPS). However, the material included in the first lower-semiconductor portion LSC1 to the sixth lower-semiconductor portion LSC6 is not limited thereto.

FIG. 5A illustrates a shape where FIG. 4A and FIG. 4B are superimposed.

Referring to FIGS. 3 and 5A, the first semiconductor pattern ACT may be disposed on the metal pattern BML. The first lower-semiconductor portion LSC1 may overlap the first lower-sub-electrode portion LSE1. The portion of the first lower-sub-electrode portion LSE1 that overlaps the first lower-semiconductor portion LSC1 may be an element constituting the sub-control electrode of the driving transistor TRD.

The second lower-semiconductor portion LSC2 may overlap the first lower-sub-

electrode portion LSE1. The third lower-semiconductor portion LSC3 may overlap the second lower-sub-electrode portion LSE2. The fifth lower-semiconductor portion LSC5 may overlap the third lower-sub-electrode portion LSE3.

FIG. 4C is a plan view of the first conductive pattern GAT1.

Referring to FIG. 4C, the first conductive pattern GAT1 may include a first lower-electrode portion LEL1, a second lower-electrode portion LEL2, a third lower-electrode portion LEL3, a fourth lower-electrode portion LEL4, a fifth lower-electrode portion LEL5, and a sixth lower-electrode portion LEL6. The second lower-electrode portion LEL2 may be spaced apart from the first lower-electrode portion LEL1. The third lower-electrode portion LEL3 may extend from one end of the second lower-electrode portion LEL2, and the fourth lower-electrode portion LEL4 may extend from the other end of the second lower-electrode portion LEL2. The fifth lower-electrode portion LEL5 may be spaced apart from the first lower-electrode portion LEL1, the second lower-electrode portion LEL2, the third lower-electrode portion LEL3, and the fourth lower-electrode portion LEL4. The sixth lower-electrode portion LEL6 may extend from one end of the fifth lower-electrode portion LEL5.

FIG. 5B illustrates a shape where FIG. 4A and FIG. 4C are superimposed.

Referring to FIGS. 3 and 5B, the first conductive pattern GAT1 may be disposed on the first semiconductor pattern ACT. The first lower-electrode portion LEL1 may overlap the first lower-semiconductor portion LSC1. The portion of the first lower-electrode portion LEL1 that overlaps the first lower-semiconductor portion LSC1 may be an element constituting the control electrode of the driving transistor TRD. The second lower-electrode portion LEL2 may overlap the second lower-semiconductor portion LSC2. The portion of the second lower-electrode portion LEL2 that overlaps the second lower-semiconductor portion LSC2 may be an element constituting the control electrode of the first emission transistor TRE1. The third lower-electrode portion LEL3 may overlap the third lower-semiconductor portion LSC3. The portion of the third lower-electrode portion LEL3 that overlaps the third lower-semiconductor portion LSC3 may be an element constituting the control electrode of the second emission transistor TRE2. The fourth lower-electrode portion LEL4 may overlap the fourth lower-semiconductor portion LSC4. The portion of the fourth lower-electrode portion LEL4 that overlaps the fourth lower-semiconductor portion LSC4 may be an element constituting the control electrode of the emission compensation transistor TRL. The fifth lower-electrode portion LEL5 may overlap the fifth lower-semiconductor portion LSC5. The portion of the fifth lower-electrode portion LEL5 that overlaps the fifth lower-semiconductor portion LSC5 may be an element constituting the control electrode of the switching transistor TRW. The sixth lower-electrode portion LEL6 may overlap the sixth lower-semiconductor portion LSC6. The portion of the sixth lower-electrode portion LEL6 that overlaps the sixth lower-semiconductor portion LSC6 may the control electrode of the second initialization transistor TRI2.

FIG. 4D is a plan view of the second conductive pattern GAT2.

Referring to FIG. 4D, the second conductive pattern GAT2 may include a first upper-sub-electrode portion HSE1, a second upper-sub-electrode portion HSE2, a third upper-sub-electrode portion HSE3, a fourth upper-sub-electrode portion HSE4, and a fifth upper-sub-electrode portion HSE5. The second upper-sub-electrode portion HSE2 may be spaced apart from the first upper-sub-electrode portion HSE1. The second upper-sub-electrode portion HSE2 may be an element constituting the sub-control electrode of the sub-compensation transistor TRS. In an embodiment of the present disclosure, the second upper-sub-electrode portion HSE2 may be omitted. The third upper-sub-electrode portion HSE3 may extend from the second upper-sub-electrode portion HSE2. The third upper-sub-electrode portion HSE3 may be an element constituting the sub-control electrode of the compensation transistor TRC. In an embodiment of the present disclosure, the third upper-sub-electrode portion HSE3 may be omitted. The fourth upper-sub-electrode portion HSE4 may be spaced apart from the first upper-sub-electrode portion HSE1, the second upper-sub-electrode portion HSE2, and the third upper-sub-electrode portion HSE3. The fourth upper-sub-electrode portion HSE4 may be an element constituting the sub-control electrode of the first initialization transistor TRI1. In an embodiment of the present disclosure, the fourth upper-sub-electrode portion HSE4 may be omitted. The fifth upper-sub-electrode portion HSE5 may be spaced apart from the first upper-sub-electrode portion HSE1, the second upper-sub-electrode portion HSE2, the third upper-sub-electrode portion HSE3, and the fourth upper-sub-electrode portion HSE4. The fifth upper-sub-electrode portion HSE5 may be electrically connected to the first initialization line INL1.

FIG. 5C illustrates a shape where FIGS. 4A through 4D are superimposed.

Referring to FIG. 5C, the second conductive pattern GAT2 may be disposed on the first conductive pattern GAT1. The first upper-sub-electrode portion HSE1 may overlap the first lower-electrode portion LEL1. A capacitor CST is defined in the region where the first upper-sub-electrode portion HSE1 and the first lower-electrode portion LEL1 overlap.

FIG. 4E is a plan view of the second semiconductor pattern OACT.

Referring to FIGS. 3 and 4E, the second semiconductor pattern OACT may include a first upper-semiconductor portion HSC1, a second upper-semiconductor portion HSC2, and a third upper-semiconductor portion HSC3. In an embodiment of the present disclosure, the third upper-semiconductor portion HSC3 may be omitted. The second upper-semiconductor portion HSC2 may be spaced apart from the first upper-semiconductor portion HSC1. The third upper-semiconductor portion HSC3 may extend from the second upper-semiconductor portion HSC2. The first upper-semiconductor portion HSC1, the second upper-semiconductor portion HSC2, and the third upper-semiconductor portion HSC3 may each be an element constituting the sub-compensation transistor TRS, the compensation transistor TRC, and the first initialization transistor TRI1, respectively. In an embodiment of the present disclosure, the first upper-semiconductor portion HSC1, the second upper-semiconductor portion HSC2, and the third upper-semiconductor portion HSC3 may each include at least one of metal oxide, crystalline oxide semiconductor, and amorphous oxide semiconductor. For example, the oxide semiconductor may include at least one of indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO).

FIG. 5D illustrates a shape where FIGS. 4A through 4E are superimposed.

Referring to FIG. 5D, the second semiconductor pattern OACT may be disposed on the second conductive pattern GAT2.

FIG. 4F is a plan view of the third conductive pattern GAT3.

Referring to FIG. 4F, the third conductive pattern GAT3 may be disposed on the second semiconductor pattern OACT. The third conductive pattern GAT3 may include a first upper-electrode portion HEL1, a second upper-electrode portion HEL2, and a third upper-electrode portion HEL3. In an embodiment of the present disclosure, the third upper-electrode portion HEL3 may be omitted. The second upper-electrode portion HEL2 may extend from one end of the first upper-electrode portion HEL1. The third upper-electrode portion HEL3 may be spaced apart from the first upper-electrode portion HEL1 and the second upper-electrode portion HEL2.

FIG. 5E illustrates a shape where FIGS. 4A through 4E are superimposed.

Referring to FIGS. 3 and 5E, the first upper-electrode portion HEL1 may overlap the first upper-semiconductor portion HSC1. The portion of the first upper-electrode portion HEL1 that overlaps the first upper-semiconductor portion HSC1 may be an element constituting the control electrode of the sub-compensation transistor TRS. The second upper-electrode portion HEL2 may overlap the second upper-semiconductor portion HSC2. The portion of the second upper-electrode portion HEL2 that overlaps the second upper-semiconductor portion HSC2 may be an element constituting the control electrode of the compensation transistor TRC. The third upper-electrode portion HEL3 may overlap the third upper-semiconductor portion HSC3. The portion of the third upper-electrode portion HEL3 that overlaps the third upper-semiconductor portion HSC3 may be an element constituting the control electrode of the first initialization transistor TRI1.

FIG. 4G is a plan view of the connection electrode pattern SD.

Referring to FIG. 4G, the connection electrode pattern SD may include a first connection electrode CNT1, a second connection electrode CNT2, a third connection electrode CNT3, a fourth connection electrode CNT4, a fifth connection electrode CNT5, a sixth connection electrode CNT6, a seventh connection electrode CNT7, an eighth connection electrode CNT8, a ninth connection electrode CNT9, a tenth connection electrode CNT10, and an eleventh connection electrode CNT11. The first through eleventh connection electrodes CNT1˜CNT11 may each be in contact with at least one of the underlying other patterns through a contact hole. Specific examples of this are described in detail below, but the present disclosure shall not be limited to these examples.

FIG. 5F illustrates a shape where FIGS. 4A through 4E are superimposed.

Referring to FIG. 5F, the connection electrode pattern SD may be disposed on the third conductive pattern GAT3.

The first connection electrode CNT1 may be in contact with the first lower-electrode portion LEL1 through a first contact hole H1. Additionally, the first connection electrode CNT1 may be in contact with the second upper-semiconductor portion HSC2 through a second contact hole H2. The first lower-electrode portion LEL1 may be an element constituting the control electrode of the driving transistor TRD. The first connection electrode CNT1 may be an element constituting the input electrode of the compensation transistor TRC. In other words, the first connection electrode CNT1 may electrically connect the control electrode of the driving transistor TRD with the input electrode of the compensation transistor TRC through the first contact hole H1 and the second contact hole H2.

The second connection electrode CNT2 may be in contact with the fourth lower-semiconductor portion LSC4 through a third contact hole H3. Additionally, the second connection electrode CNT2 may be in contact with the first lower-sub-electrode portion LSE1 through a fourth contact hole H4. The second connection electrode CNT2 may be an element constituting the output electrode of the emission compensation transistor TRL. The first lower-sub-electrode portion LSE1 may be an element constituting the sub-control electrode of the driving transistor TRD. In other words, the second connection electrode CNT2 may electrically connect the output electrode of the emission compensation transistor TRL with the sub-control electrode of the driving transistor TRD through the third contact hole H3 and the fourth contact hole H4.

The third connection electrode CNT3 may be in contact with the first upper-semiconductor portion HSC1 through a fifth contact hole H5. Additionally, the third connection electrode CNT3 may be in contact with the first lower-sub-electrode portion LSE1 through a sixth contact hole H6. The third connection electrode CNT3 may be an element constituting the input electrode of the sub-compensation transistor TRS. The first lower-sub-electrode portion LSE1 may be an element constituting the sub-control electrode of the driving transistor TRD. In other words, the third connection electrode CNT3 may electrically connect the input electrode of the sub-compensation transistor TRS with the sub-control electrode of the driving transistor TRD through the fifth contact hole H5 and the sixth contact hole H6.

The fourth connection electrode CNT4 may be in contact with the first upper-semiconductor portion HSC1 through a seventh contact hole H7. Additionally, the fourth connection electrode CNT4 may be in contact with the third lower-sub-electrode portion LSE3 through an eighth contact hole H8. The fourth connection electrode CNT4 may be an element constituting the input electrode of the sub-compensation transistor TRS. The third lower-sub-electrode portion LSE3 may be electrically connected to the compensation signal line GCL. In other words, the fourth connection electrode CNT4 may electrically connect the input electrode of the sub-compensation transistor TRS to the compensation signal line GCL through the eighth contact hole H8 and a ninth contact hole H9.

The fifth connection electrode CNT5 may be in contact with the second lower-sub-electrode portion LSE2 through the ninth contact hole H9. Additionally, the fifth connection electrode CNT5 may be in contact with the fourth lower-semiconductor portion LSC4 through a tenth contact hole H10. The second lower-sub-electrode portion LSE2 may be electrically connected to the power line PL. The fifth connection electrode CNT5 may be an element constituting the input electrode of the emission compensation transistor TRL. In other words, the fifth connection electrode CNT5 may electrically connect the input electrode of the emission compensation transistor TRL to the power line PL through the tenth contact hole H10 and an eleventh contact hole H11.

The sixth connection electrode CNT6 may be in contact with the second lower-

semiconductor portion LSC2 through the eleventh contact hole H11. The sixth connection electrode CNT6 may electrically connect the second lower-semiconductor portion LSC2 to at least one component of the first semiconductor pattern ACT. The seventh connection electrode CNT7 may be in contact with the third lower-semiconductor portion LSC3 through a thirteenth contact hole H13.

The eighth connection electrode CNT8 may be in contact with at least one of the first lower-semiconductor portion LSC1 and the third lower-semiconductor portion LSC3 through a fourteenth contact hole H14. Additionally, the eighth connection electrode CNT8 may be in contact with the second upper-semiconductor portion HSC2 through the fifteenth contact hole H15. In other words, the eighth connection electrode CNT8 may electrically connect the compensation transistor TRC to at least one of the driving transistor TRD and the second emission transistor TRE2 through the fourteenth contact hole H14 and a fifteenth contact hole H15.

The ninth connection electrode CNT9 may be in contact with the sixth lower-semiconductor portion LSC6 through a sixteenth contact hole H16. The ninth connection electrode CNT9 may be electrically connected to the second initialization line INL2. The tenth connection electrode CNT10 may be in contact with the fifth lower-semiconductor portion LSC5 through a seventeenth contact hole H17.

The eleventh connection electrode CNT11 may be in contact with the third upper-semiconductor portion HSC3 through an eighteenth contact hole H18. Additionally, the eleventh connection electrode CNT11 may be in contact with the fifth upper-sub-electrode portion HSE5 through a nineteenth contact hole H19. The fifth upper-sub-electrode portion HSE5 may be electrically connected to the first initialization line INL1. In other words, the eleventh connection electrode CNT11 may electrically connect the input electrode of the first initialization transistor TRI1 to the first initialization line INL1 through the eighteenth contact hole H18 and the nineteenth contact hole H19.

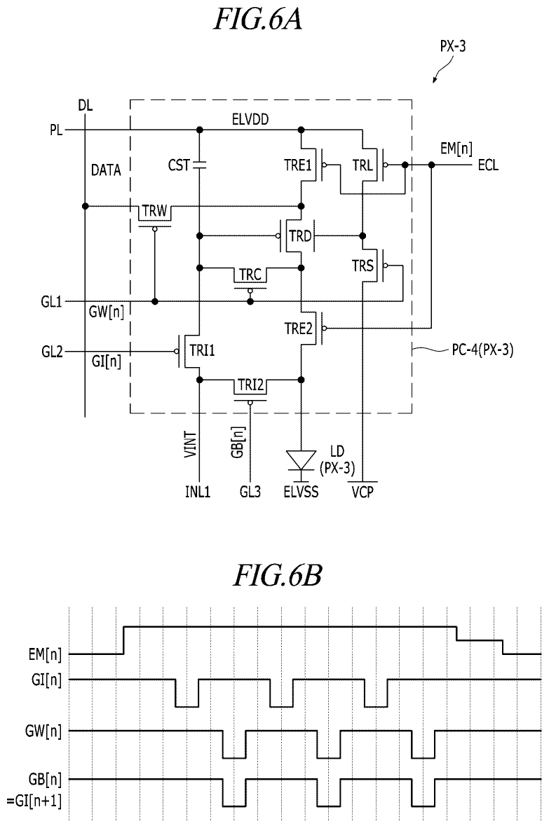

FIG. 6A is an exemplary equivalent circuit diagram illustrating a pixel PX-3 according to an embodiment of the present disclosure. FIG. 6B is a waveform diagram illustrating signals provided to the pixels PX-3 according to an embodiment of the present disclosure.

Referring to FIG. 6A, the display panel DP according to an embodiment of the present disclosure may include a data line DL, a power line PL, a first gate line GL1, a second gate line GL2, a first initialization line INL1, a third gate line GL3, an emission control line ECL, and a pixel PX-3. In an embodiment of the present disclosure, at least one of the second gate line GL2, the first initialization line INL1, the third gate line GL3, and the emission control line ECL may be omitted.

The data line DL may be configured to provide a data signal DS to the pixel PX-3. The power line PL may be configured to provide a first power signal ELVDD to the pixel PX-3. The first gate line GL1 may be configured to provide a first gate signal GW to the pixel PX-3. The second gate line GL2 may be configured to provide a second gate signal GI to the pixel PX-3. The first initialization line INL1 may be configured to provide a first initialization signal VINT to the pixel PX-3. The third gate line GL3 may be configured to provide a third gate signal GB to the pixel PX-3. The emission control line ECL may be configured to provide an emission control signal EM to the pixel PX-3. The pixel PX-3 may include a pixel circuit PC-4 and a light-emitting diode LD.

The pixel circuit PC-4 may include a driving transistor TRD, a switching transistor TRW, a compensation transistor TRC, a sub-compensation transistor TRS, a first emission transistor TRE1, a second emission transistor TRE2, an emission compensation transistor TRL, a capacitor CST, a first initialization transistor TRI1, and a second initialization transistor TRI2. In an embodiment of the present disclosure, at least one of the sub-compensation transistor TRS, the first emission transistor TRE1, the second emission transistor TRE2, the emission compensation transistor TRL, the capacitor CST, the first initialization transistor TRI1, and the second initialization transistor TRI2 may be omitted in the pixel circuit PC-4.

In an embodiment of the present disclosure, the pixel PX-3 may be a low-temperature polycrystalline silicon (LTPS) pixel. That is, the driving transistor TRD, the switching transistor TRW, the compensation transistor TRC, the sub-compensation transistor TRS, the first emission transistor TRE1, the second emission transistor TRE2, the emission compensation transistor TRL, the first initialization transistor TRI1, and the second initialization transistor TRI2 may each be an LTPS thin-film transistor.

In an embodiment of the present disclosure, the driving transistor TRD, the switching transistor TRW, the compensation transistor TRC, the sub-compensation transistor TRS, the first emission transistor TRE1, the second emission transistor TRE2, the emission compensation transistor TRL, the first initialization transistor TRI1, and the second initialization transistor TRI2 may each be a PMOS transistor. In an embodiment of the present disclosure, the driving transistor TRD, the switching transistor TRW, the compensation transistor TRC, the sub-compensation transistor TRS, the first emission transistor TRE1, the second emission transistor TRE2, the emission compensation transistor TRL, the first initialization transistor TRI1, and the second initialization transistor TRI2 may each be an NMOS transistor. However, the present disclosure is not limited to these configurations, and the pixel PX-3 may be configured with various combinations of NMOS and PMOS transistors.

The driving transistor TRD may be electrically connected to the light-emitting diode LD. The driving transistor TRD may include an input electrode, an output electrode, a control electrode, and a sub-control electrode.

The switching transistor TRW may be configured to be controlled by the first gate signal GW. The switching transistor TRW may be disposed between the data line DL and the driving transistor TRD.

The compensation transistor TRC may be disposed between the output electrode of the driving transistor TRD and the control electrode of the driving transistor TRD. The compensation transistor TRC may be configured to be controlled by the first gate signal GW. That is, in the display panel DP according to an embodiment of the present disclosure, the compensation transistor TRC is configured to be controlled by the compensation control signal GC, whereas in FIG. 6A, the compensation transistor TRC may be configured to be controlled by the first gate signal GW.

The sub-compensation transistor TRS may be configured to transfer the compensation signal VCP to the sub-control electrode of the driving transistor TRD. The sub-compensation transistor TRS may be configured to be controlled by the same signal GW as the compensation transistor. In an embodiment of the present disclosure, the voltage value of the compensation signal VCP may be greater than the voltage value of the first power signal ELVDD. In an embodiment of the present disclosure, the voltage value of the compensation signal VCP may decrease when the ambient temperature decreases.

The first emission transistor TRE1 may be configured to be controlled by the emission control signal EM. The first emission transistor TRE1 may be disposed between the power line PL and the driving transistor TRD.

The second emission transistor TRE2 may be configured to be controlled by the emission control signal EM. The second emission transistor TRE2 may be disposed between the driving transistor TRD and the light-emitting diode LD.

The emission compensation transistor TRL may be configured to be controlled by the emission control signal EM. The emission compensation transistor TRL may be disposed between the power line PL and the sub-control electrode of the driving transistor TRD.

The capacitor CST may be disposed between the power line PL and the compensation transistor TRC.

The first initialization transistor TRI1 may be disposed between the first initialization line INL1 and the control electrode of the driving transistor TRD. The first initialization transistor TRI1 may be configured to be controlled by the second gate signal GI. The first initialization transistor TRI1 may be configured to be turned on in response to the second gate signal GI and to transfer at least part of the first initialization signal VINT to the control electrode of the driving transistor TRD.

The second initialization transistor TRI2 may be disposed between the first initialization line INL1 and the light-emitting diode LD. The input electrode of the second initialization transistor TRI2 may be electrically connected to the first initialization transistor TRI1 and the first initialization line INL1. The output electrode of the second initialization transistor TRI2 may be electrically connected to the second emission transistor TRE2 and the light-emitting diode LD.

The second initialization transistor TRI2 may be configured to be controlled by the third gate signal GB. The second initialization transistor TRI2 may be configured to be turned on in response to the third gate signal GB and to transfer at least part of the first initialization signal VINT to the light-emitting diode LD.

One end of the light-emitting diode LD may be electrically connected to the second emission transistor TRE2, and the other end of the light-emitting diode LD may be supplied with the second power signal ELVSS. In an embodiment of the present disclosure, the voltage value of the second power signal ELVSS may range from about −0.9 V to about −1.9 V. For example, the voltage value of the second power signal ELVSS may be about −1.4 V. However, the voltage value of the second power signal ELVSS is not limited thereto.

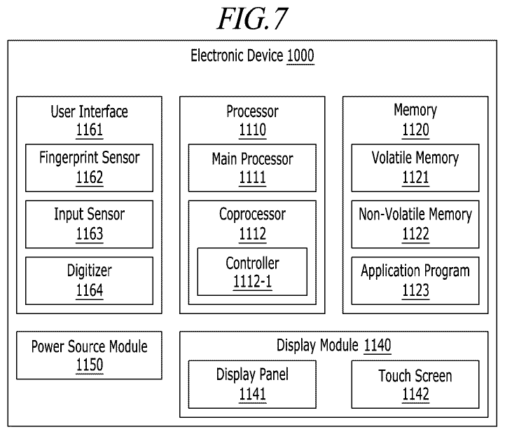

FIG. 7 is a diagram illustrating an electronic device according to an embodiment of the present disclosure.

Referring to FIG. 7, the electronic device 1000 according to an embodiment of the present disclosure may output various information (e.g., images, text, music, etc.) through a display module 1140, which, for example, may correspond to the display device DD described above. When a processor 1110 executes an application stored in a memory 1120, the display module 1140 may provide application information to a user through a display panel 1141. The display panel 1141 may correspond to the display panel DP described above.

In some embodiments, the electronic device 1000 may be configured as, for example, a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include software designed to execute specific tasks or provide functionality to a user. The application program 1123 may operate under the control of the processor 1110 and utilizes data stored in the memory 1120 to deliver a wide range of features, such as, for example, productivity tools, multimedia streaming and playback, file or mail deliveries or communication services. The application program 1123 interacts seamlessly with the user interface 1161 or touch screen 1142, allowing a user to launch, navigate, and utilize the program through user inputs such as, for example, touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

In an embodiment, when a user wishes to make a phone call, the user taps the telephone icon displayed on the display module 1140, and the processor 1110 may execute a phone application program stored in the memory 1120. A telephone keypad may be presented on the display panel 1141 for the user to enter a phone number to call.

In an embodiment, the display module 1140 may be integrated into an electronic device 1000, such as, for example, a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD described above.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as, for example, blood pressure, moisture, or body mass.

The input sensor 1163 may sense user interactions including, for example, touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include, for example, a liquid crystal display panel, an organic light emitting display panel, or an inorganic light emitting display panel. However, the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device DD described above.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power to each of the components described above including the display module 1140.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display panel, comprising:
a pixel comprising a pixel circuit and a light-emitting diode;
a data line configured to provide a data signal to the pixel;
a gate line configured to provide a gate signal to the pixel; and
a power line configured to provide a power signal to the pixel,
wherein the pixel circuit comprises:
a driving transistor electrically connected to the light-emitting diode and comprising an input electrode, an output electrode, a control electrode, and a sub-control electrode;
a switching transistor configured to be controlled by the gate signal and disposed between the data line and the driving transistor;
a compensation transistor disposed between the output electrode and the control electrode of the driving transistor; and
a sub-compensation transistor configured to transfer a compensation signal to the sub-control electrode of the driving transistor and configured to be controlled by a same signal as the compensation transistor.

2. The display panel of claim 1, wherein a voltage value of the compensation signal is greater than a voltage value of the power signal.

3. The display panel of claim 1, wherein a voltage value of the compensation signal decreases as an ambient temperature decreases.

4. The display panel of claim 1, further comprising:
an emission control line configured to provide an emission control signal to the pixel;
a first emission transistor configured to be controlled by the emission control signal and disposed between the power line and the driving transistor;
a second emission transistor configured to be controlled by the emission control signal and disposed between the driving transistor and the light-emitting diode; and
an emission compensation transistor configured to be controlled by the emission control signal and disposed between the power line and the sub-control electrode of the driving transistor.

5. The display panel of claim 1, further comprising:
a capacitor disposed between the power line and the compensation transistor.

6. The display panel of claim 1, further comprising:
a first initialization line configured to provide a first initialization signal to the pixel; and
a first initialization transistor disposed between the first initialization line and the control electrode of the driving transistor and configured to be turned on simultaneously with the compensation transistor for a predetermined period.

7. The display panel of claim 1, further comprising:
a second initialization line configured to provide a second initialization signal to the pixel; and
a second initialization transistor disposed between the second initialization line and the light-emitting diode and configured to transfer the second initialization signal to the light-emitting diode.

8. The display panel of claim 7, further comprising:
a bias signal line configured to provide a bias signal to the pixel; and
a bias transistor disposed between the bias signal line and the driving transistor and configured to be controlled by a same signal as the second initialization transistor.

9. A display panel, comprising:
a pixel comprising a pixel circuit and a light-emitting diode;
a data line configured to provide a data signal to the pixel;
a gate line configured to provide a gate signal to the pixel;
a power line configured to provide a power signal to the pixel; and
an emission control line configured to provide an emission control signal to the pixel,
wherein the pixel circuit comprises:
a driving transistor electrically connected to the light-emitting diode and comprising an input electrode, an output electrode, a control electrode, and a sub-control electrode;
a switching transistor configured to be controlled by the gate signal and disposed between the data line and the driving transistor;
a first emission transistor configured to be controlled by the emission control signal and disposed between the power line and the driving transistor;
a second emission transistor configured to be controlled by the emission control signal and disposed between the driving transistor and the light-emitting diode; and
an emission compensation transistor configured to be controlled by the emission control signal and disposed between the power line and the sub-control electrode of the driving transistor.

10. The display panel of claim 9, further comprising:
a compensation transistor disposed between the output electrode and the control electrode of the driving transistor; and
a sub-compensation transistor configured to transfer a compensation signal to the sub-control electrode of the driving transistor and configured to be controlled by a same signal as the compensation transistor.

11. The display panel of claim 10, wherein a voltage value of the compensation signal is greater than a voltage value of the power signal.

12. The display panel of claim 11, wherein the voltage value of the compensation signal decreases as an ambient temperature decreases.

13. The display panel of claim 12, further comprising:
a capacitor disposed between the power line and the compensation transistor.

14. The display panel of claim 13, further comprising:
a first initialization line configured to provide a first initialization signal to the pixel; and
a first initialization transistor disposed between the first initialization line and the control electrode of the driving transistor and configured to be turned on simultaneously with the compensation transistor for a predetermined period.

15. The display panel of claim 14, further comprising:
a second initialization line configured to provide a second initialization signal to the pixel; and
a second initialization transistor disposed between the second initialization line and the light-emitting diode and configured to transfer the second initialization signal to the light-emitting diode.

16. The display panel of claim 15, further comprising:
a bias signal line configured to provide a bias signal to the pixel; and
a bias transistor disposed between the bias signal line and the driving transistor and configured to be controlled by a same signal as the second initialization transistor.

17. The display panel of claim 16, wherein a voltage value of the data signal is greater than or equal to about 0.5 V and smaller than or equal to about 6.8 V,
a voltage value of the bias signal is greater than or equal to about 5.0 V and smaller than or equal to about 6.0V,
the voltage value of the power signal is greater than or equal to about 4.1 V and smaller than or equal to about 5.1 V,
a voltage value of the first initialization signal is greater than or equal to about −3.0 V and smaller than or equal to about −2.0 V, and
a voltage value of the second initialization signal is greater than or equal to about −1.9 V and smaller than or equal to about −0.5 V.

18. An electronic device, comprising:
a processor;
a memory having stored application programs for execution by the processor;
a display device, comprising:
a display panel,
wherein the display panel comprises:
a pixel comprising a pixel circuit and a light-emitting diode;
a data line configured to provide a data signal to the pixel;
a gate line configured to provide a gate signal to the pixel; and
a power line configured to provide a power signal to the pixel,
wherein the pixel circuit comprises:
a driving transistor electrically connected to the light-emitting diode and comprising an input electrode, an output electrode, a control electrode, and a sub-control electrode;
a switching transistor configured to be controlled by the gate signal and disposed between the data line and the driving transistor;
a compensation transistor disposed between the output electrode and the control electrode of the driving transistor; and
a sub-compensation transistor configured to transfer a compensation signal to the sub-control electrode of the driving transistor and configured to be controlled by a same signal as the compensation transistor; and
a user interface configured to sense user input via touch or cursor select of an icon presented on the display panel, wherein the processor is caused to execute one or more of the stored application programs upon receipt of the user input.

19. The electronic device of claim 18, wherein the stored application programs include one or more of a camera application, an audiovisual streaming application, or a telephone application.

20. The electronic device of claim 18, wherein the user interface is a touch screen embedded in the display panel, wherein the touch screen includes touch sensors for sensing a touch or a tap by a user.
